(19) United States
(12) Patent Application Publication
(10) Pub. No.: US 2026/0086461 A1
(43) Pub. Date: Mar. 26, 2026

(54) SEMICONDUCTOR DEVICE MANUFACTURING METHOD

(71) Applicant: Kioxia Corporation, Tokyo (JP)

(72) Inventors: Hirotoshi YAMAMOTO, Yokkaichi Mie (JP); Hiroshi TOMITA, Muko Kyoto (JP); Toshiyuki MURANAKA, Yokkaichi Mie (JP); Ryutaro OTAHARA, Yokkaichi Mie (JP); Yusuke OSHIMA, Yokkaichi Mie (JP)

(73) Assignee: Kioxia Corporation, Tokyo (JP)

(21) Appl. No.: 19/070,164

(22) Filed: Mar. 4, 2025

(30) Foreign Application Priority Data
Sep. 20, 2024 (JP) 2024-163624

(51) Int. Cl. G03F 7/16; G01N 21/41; G01N 21/95

(52) U.S. Cl. CPC G03F 7/162; G01N 21/41; G01N 21/9501

(57) ABSTRACT

A semiconductor device manufacturing method of embodiments includes: performing a first supply of a chemical solution from an application nozzle onto a surface of a wafer; storing the application nozzle in a container; performing a second supply of a solvent into the container; measuring first defects in the solvent discharged from the container; performing the first supply of the chemical solution from the application nozzle onto the surface of the wafer when the number of first defects is less than a first threshold value; and continuing the second supply of the solvent into the container when the number of first defects is equal to or greater than the first threshold value.

### CROSS-REFERENCE TO RELATED APPLICATION

This application is based upon and claims the benefit of priority from Japanese Patent Application No. 2024-163624, filed on Sep. 20, 2024, the entire contents of which are incorporated herein by reference.

### FIELD

Embodiments described herein relate generally to a semiconductor device manufacturing method.

### BACKGROUND

Processes for manufacturing a semiconductor device include a process of applying a resist liquid to a substrate to form a resist pattern. The resist liquid is applied, for example, by discharging the resist liquid from a nozzle onto approximately the central portion of a semiconductor wafer (hereinafter, referred to as a “wafer”) held by a spin chuck while rotating the wafer.

### BRIEF DESCRIPTION OF THE DRAWINGS

FIG. 1 is a schematic diagram showing a semiconductor manufacturing factory of embodiments;

FIG. 2 is a schematic diagram of a resist film forming apparatus of embodiments;

FIG. 3 is a schematic perspective view of a main part of the resist film forming apparatus of embodiments;

FIG. 4 is a schematic diagram showing a solvent bath and an application nozzle housed in the solvent bath of embodiments;

FIGS. 5A and 5B are schematic diagrams of a defect detection cell (evaluation unit, or evaluator) that is used in a first defects inspection apparatus and a second defects inspection apparatus of embodiments to acquire the particle sizes of defects using an FPT method;

FIG. 6 shows an example of evaluation of a liquid containing defects, which is performed using a defect detection cell (evaluation unit) of embodiments; and

FIG. 7 is a flowchart showing a semiconductor device manufacturing method of embodiments.

### DETAILED DESCRIPTION

A semiconductor device manufacturing method of embodiments includes: performing a first supply of a chemical solution from an application nozzle onto a surface of a wafer; storing the application nozzle in a container; performing a second supply of a solvent into the container; measuring first defects in the solvent discharged from the container; performing the first supply of the chemical solution from the application nozzle onto the surface of the wafer when the number of first defects is less than a first threshold value; and continuing the second supply of the solvent into the container when the number of first defects is equal to or greater than the first threshold value.

Hereinafter, embodiments will be described with reference to the diagrams. In addition, in the diagrams, the same or similar portions are denoted by the same or similar reference numerals.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

Here, an X-axis, a Y-axis perpendicular to the X-axis, and a Z-axis perpendicular to the X-axis and the Y-axis are defined. The Z-axis is a direction opposite to the vertical direction.

The “chemical solution” in embodiments is, for example, a resist mixture containing a resist solvent, a polymer resin, a photosensitizer, and an additive. In addition, the “solvent” in embodiments is an organic solvent for cleaning the application nozzle. The “solvent” in embodiments is, for example, a resist solvent used in the “chemical solution”.

### Embodiments

A semiconductor device manufacturing method of embodiments includes: performing a first supply of a chemical solution from an application nozzle onto a surface of a wafer; storing the application nozzle in a container; performing a second supply of a solvent into the container; measuring first defects in the solvent discharged from the container; performing the first supply of the chemical solution from the application nozzle onto the surface of the wafer when the number of first defects is less than a first threshold value; and continuing the second supply of the solvent into the container when the number of first defects is equal to or greater than the first threshold value.

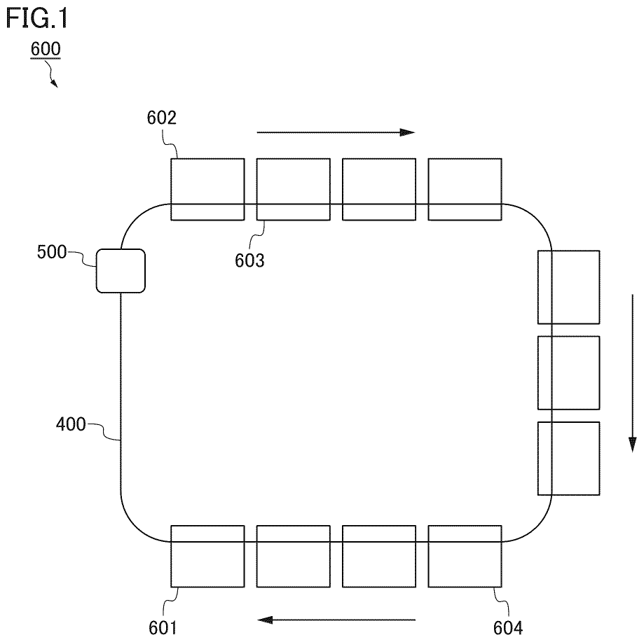

FIG. 1 is a schematic diagram showing a semiconductor manufacturing factory 1000 of embodiments.

The semiconductor manufacturing factory 1000 includes a plurality of manufacturing apparatuses, such as a dry etching apparatus 601, a sputtering apparatus 602, a chemical vapor deposition (CVD) apparatus 603, and a resist film forming apparatus 604 as an application apparatus having a chemical solution ejection nozzle. In addition, manufacturing apparatuses provided in the semiconductor manufacturing factory 1000 are not particularly limited, but may include a heat treatment apparatus, a cleaning and drying apparatus, an ion implantation apparatus, a sputtering apparatus, a chemical mechanical polishing (CMP) apparatus, and the like.

The semiconductor manufacturing apparatus used in the semiconductor device manufacturing method of embodiments is, for example, the resist film forming apparatus 604.

A track 400 is provided close to the plurality of manufacturing apparatuses described above. A front opening unified pod (FOUP) 500 is a container used for transporting and loading wafers into each apparatus. The FOUP 500 is movable along the track 400.

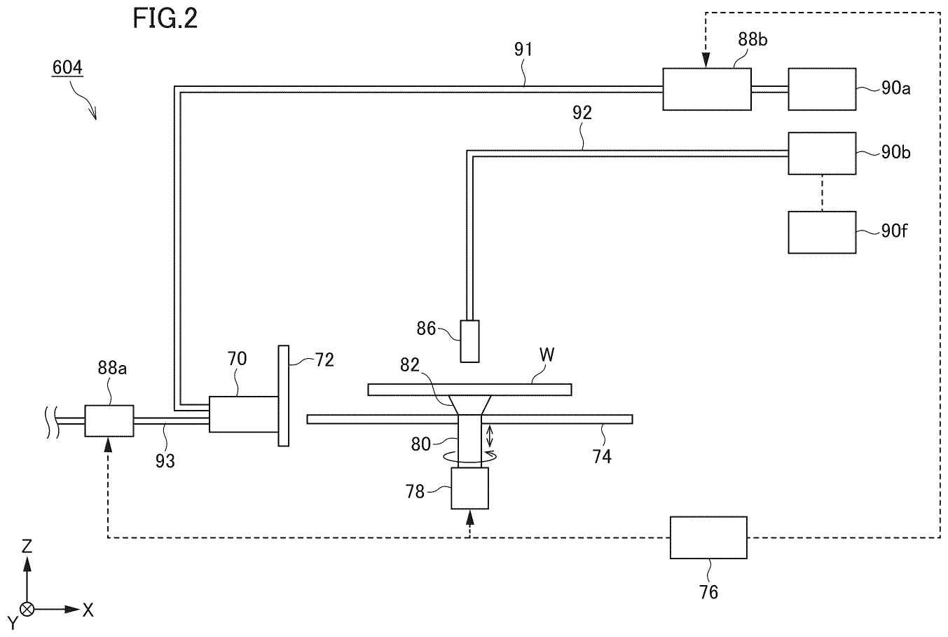

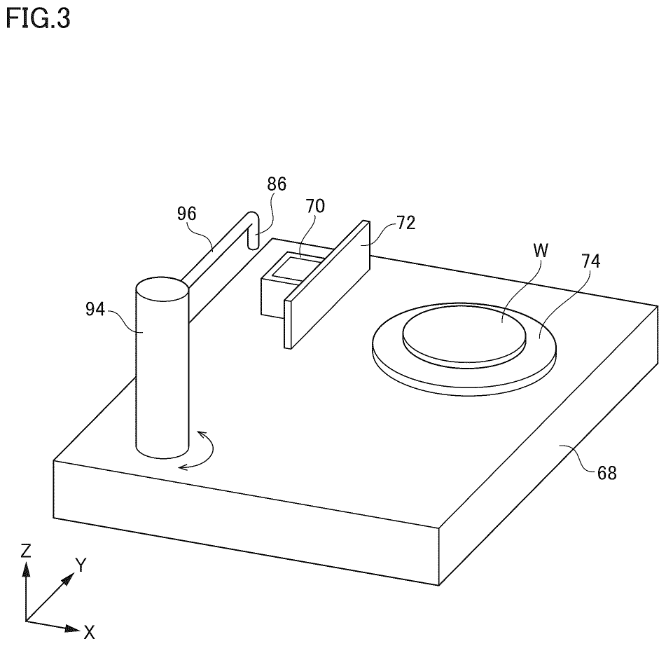

FIG. 2 is a schematic diagram of the resist film forming apparatus 604 of embodiments. FIG. 3 is a schematic perspective view of a main part of the resist film forming apparatus 604 of embodiments.

The resist film forming apparatus 604 of embodiments will be described with reference to FIGS. 2 and 3.

A central portion of the back surface of a wafer W is adsorbed by a spin chuck 82 and held horizontally. The spin chuck 82 can rotate the wafer W in a plane perpendicular to the Z-axis while holding the wafer W by a driving mechanism 78 through a driving shaft 80. In addition, the spin chuck 82 can raise and lower the wafer W in a direction parallel to the Z-axis. A tray 74 is provided around the driving shaft 80 to receive a chemical solution when the chemical solution applied to the wafer W is scattered around the wafer W. The driving mechanism 78 is, for example, a motor.

A chemical solution for forming a resist film is supplied from a chemical solution supply source 90b and from above the wafer W onto the surface of the wafer W through a pipe 92 using an application nozzle 86. In addition, as shown in FIG. 2, a plurality of chemical solution supply sources 90 (90a, 90b, . . . , 90f) may be provided to supply different types of chemical solutions. In the resist film forming apparatus 604 of embodiments, the number of chemical solution supply sources 90 is not particularly limited.

The application nozzle 86 waits in a solvent bath (an example of a container) 70 while the chemical solution is not being discharged. The solvent bath 70 is, for example, a container capable of containing a solvent therein. By immersing the application nozzle 86 in the solvent in the solvent bath 70, a dried resist and dust adhering to the application nozzle 86 are washed away. The movement of the application nozzle 86 between the solvent bath 70 and above the wafer W is performed, for example, by using a rotation mechanism 94 connected to an arm 96 that holds the application nozzle 86. For example, the pipe 92 is built into the arm 96. The rotation mechanism 94 is, for example, a motor.

In addition, between the solvent bath 70 and the wafer W, a partition plate 72 is provided to prevent the chemical solution scattered around the wafer W from entering the solvent bath 70.

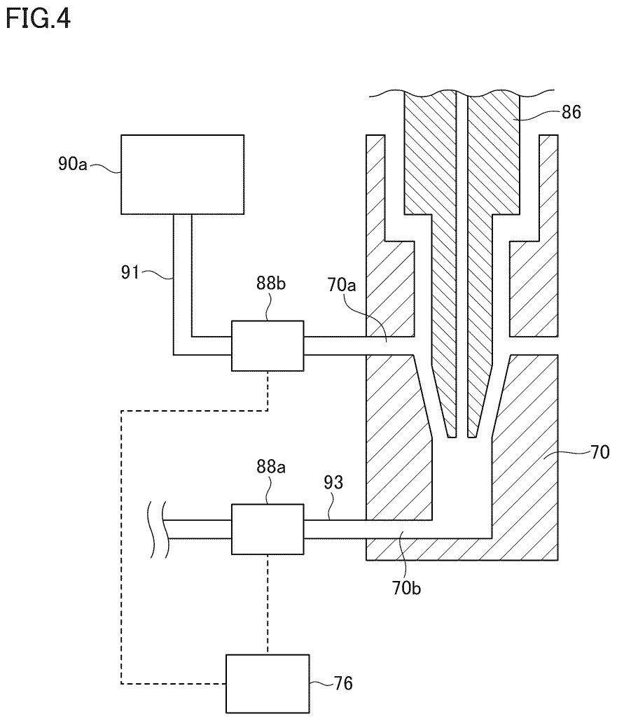

FIG. 4 is a schematic diagram showing the solvent bath 70 and the application nozzle 86 housed in the solvent bath 70. For example, it is assumed that a solvent for cleaning the application nozzle 86 is stored in the chemical solution supply source 90a. The solvent in the chemical solution supply source 90a is supplied from a supply path 70a into the solvent bath 70 through a pipe 91. The supplied solvent cleans the application nozzle 86, and is then discharged from a discharge path 70b and supplied to a first defects inspection apparatus 88a through a pipe 93. In the first defects inspection apparatus 88a, first defects in the solvent after the application nozzle 86 is cleaned are inspected. In addition, the positional relationships of the components shown in FIGS. 2 to 4 are not the same.

In addition, it is more preferable that a second defects inspection apparatus 88b is provided on the pipe 91 to inspect second defects in the solvent before the solvent is supplied to the container.

A control device 76 rotates and raises and lowers the wafer W using the spin chuck 82, inspects defects in the solvent using the first defects inspection apparatus 88a and the second defects inspection apparatus 88b, and moves the application nozzle 86 between the solvent bath 70 and above the wafer W using the rotation mechanism 94.

The control device 76 is, for example, an electronic circuit. The control device 76 is, for example, a computer configured by a combination of hardware, such as an arithmetic circuit, and software, such as a program.

Here, the structures of the first defects inspection apparatus 88a and the second defects inspection apparatus 88b will be described. The first defects inspection apparatus 88a and the second defects inspection apparatus 88b are inspection apparatuses that use a method of evaluating the presence or absence of defects in the resist liquid as the presence or absence of a light scatterer by using, for example, a light scattering method (liquid particle counter: LPC).

More specifically, this defects evaluation method is a method of measuring the size of defects with a measuring instrument using the light scattering intensity of a light scatterer. In addition, the measuring instrument is calibrated using the light scattering intensity of standard particles. Here, as the standard particles, for example, polystyrene latex particles having different sizes are used.

Alternatively, the first defects inspection apparatus 88a and the second defects inspection apparatus 88b are inspection apparatuses that acquire particle sizes (geometric sizes) of defects by using, for example, a flow particle tracking (FPT) method.

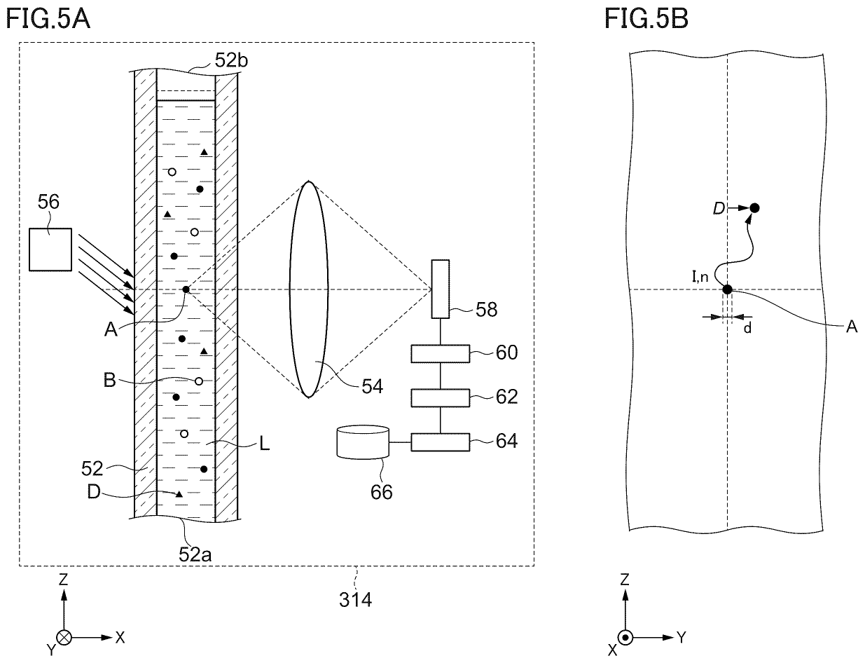

FIGS. 5A and 5B are schematic diagrams of a defect detection cell (evaluation unit) 314 that is used in the first defects inspection apparatus 88a and the second defects inspection apparatus 88b to acquire the particle sizes of defects using the FPT method. FIG. 5A is a schematic diagram of the defect detection cell 314 of embodiments.

A column 52 is a transparent container capable of containing a solvent. The flow of the solvent in the column 52 is a laminar flow in the Z-axis direction. The column 52 is formed of, for example, synthetic quartz or sapphire. The solvent flows from a column inlet 52a to a column outlet 52b of the column 52.

An irradiation unit (light source) 56 irradiates the solvent in the column 52 with irradiation light such as laser light. For example, when the solvent flows in the Z-axis direction, the irradiation unit 56 irradiates the solvent with irradiation light in the X-axis direction. The irradiation direction of the irradiation light is not limited to the X-axis direction.

An imaging unit (imager) 58 includes a charge coupled device (CCD) sensor, a complementary metal oxide semiconductor (CMOS) sensor, and the like (not shown). The imaging unit 58 uses a lens 54 and the like to image the solvent in the column 52. Then, moving images of the scattered light emitted from the defects are acquired. FIG. 5B is an example of the schematic diagram of a moving image of a metal particle A acquired by the imaging unit 58. An analyzing unit (analyzer) 60 obtains a diffusion coefficient D of a bubble B, the metal particle A, and a particle D different from the bubble B and the metal particle A from the moving image. Here, the metal particle A is an example of the first particle. In addition, the particle D is an example of the second particle. The particle D is, for example, a particle of carbon, silica (quartz), or fluororesin.

When the defects perform Brownian motion in the solvent, the diffusion coefficient D of the defects can be determined from the moving image of the scattered light of the defects. The diffusion coefficient D and the particle size d of the defects are related by the following equation.

$$\begin{matrix}[ Equation 1 ] & \\ D = \frac{{k}_{B} T}{3 πη d} & ( 1 )\end{matrix}$$

In Equation (1), D is the diffusion coefficient of the defects, KB is Boltzmann's constant, T is the absolute temperature, n is the viscosity (viscosity factor) of the solvent, and d is the particle size of the defects. A calculating unit (calculator) 62 can determine the particle size d of the defects from the diffusion coefficient D using Equation (1).

In addition, the refractive index of the defects can be obtained from the following equation.

$$\begin{matrix}[ Equation 2 ] & \\ I ∝ {I}_{0} \frac{c}{2 {r}^{2}} {( \frac{2 π}{λ} )}^{4} {( \frac{d}{2} )}^{6} {\vert \frac{{m}^{2} - 1}{{m}^{2} + 2} \vert}^{2} & ( 2 )\end{matrix}$$

In Equation (2), I is the intensity of the scattered light, I₀ is the intensity of the incident light, c is the number concentration of the defects, r is the distance from the defects to the imaging unit 58, λ is the wavelength of the incident light, d is the particle size of the defects, and m is the relative refractive index of the defects with respect to the solvent. The relative refractive index m is the refractive index n of the defects divided by the refractive index no of the solvent (m=n/n0). If the refractive index no of the first mixture or the second mixture is known, the calculating unit 62 can determine the refractive index n of the defects using Equation (2). A determination unit (determinator) 64 determines whether the defects are bubbles or the metal defects A or the particles D using the refractive index n determined by the calculating unit 62. For example, the determination unit 64 is connected to a database 66 in which the refractive index of a known substance is stored. For example, the determination unit 64 refers to the refractive index of such known substance in the above determination.

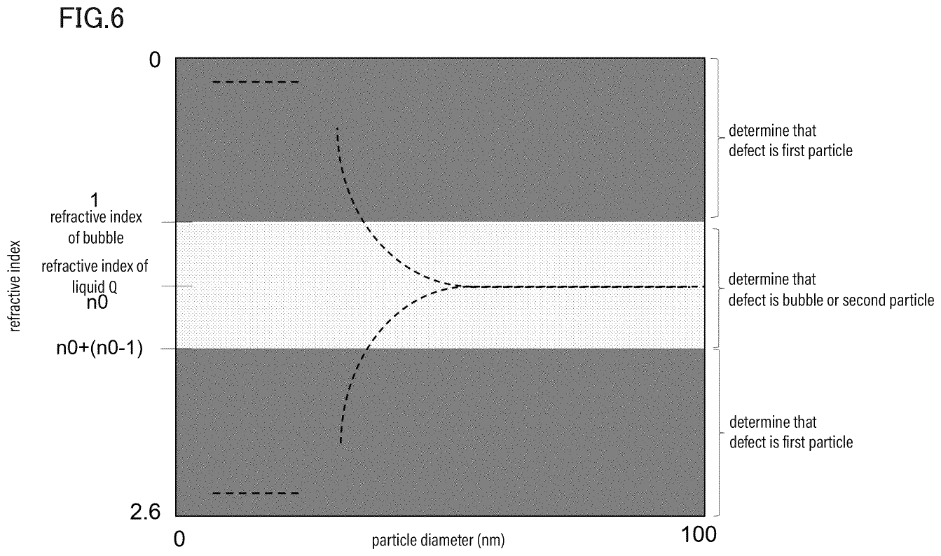

FIG. 6 shows an example of the evaluation of a liquid containing the defects using a defect detection cell (evaluation unit) 314 of embodiments. The plot shown in FIG. 6 is the particle size d of the defects with the horizontal axis and the refractive index n of the defects calculated by the calculating unit 62 with the vertical axis.

FIG. 6 shows similar distributions at the top and the bottom, centered on the refractive index no of the solvent. In other words, the calculating unit 62 provides two refractive indices n around the refractive index no of the solvent for the same particle size d. This is because Equation (2) is a quadratic equation of the relative refractive index m. Therefore, by comparing the relative refractive index m obtained by Equation (2) with known refractive index data, the evaluation method of embodiments becomes a semi-qualitative method.

Specifically, when the refractive index of the solvent to be measured is taken as no, it is preferable that the determination unit 64 determines that the defects are the metal particles when the refractive index n is larger than n0+ (n0−1) or the refractive index n is smaller than 1. In addition, when the refractive index of the solvent to be measured is taken as no, it is preferable that the determination unit 64 determines that the defects are the bubbles or the particles D when the refractive index n is 1 or more or n0+ (n0−1) or less. In other words, centered on the refractive index n0 of the solvent, when the refractive index n within the range of the difference between the refractive index n0 of the solvent and the refractive index 1 of the bubble is calculated, it is determined that the defects contain the particle D or the bubble. Further, centered on the refractive index n0 of the solvent, when the refractive index n out of the range of the difference between the refractive index n0 of the solvent and the refractive index 1 of the bubble is calculated, it is determined that the defects contain the metal particle A. That is, assuming that the refractive index of the solvent to be measured is n0, the determination unit 64 determines that the defects contain the metal particle A if the refractive index n satisfies “n<1” or “n0+(n0−1)<n”, and determines that the defects contain the particle D or the bubble if the refractive index n satisfies “1≤n≤n0+(n0−1)”. The refractive index n0 of the solvent to be measured is, for example, 1.2 to 1.5, but is not limited thereto.

Note that the database 66 may not be provided. The determination unit 64 may distinguish the bubble from the metal particle by simply using the magnitude relation of the refractive index.

In embodiments, dust in the chemical solution is referred to as defects. In addition, in embodiments, the bubble B, the metal particle A, and the particle D different from the bubble B and the metal particle A in the chemical solution, which are measured using the FPT method, are collectively referred to as defects.

The database 66 is, for example, a storage device such as a semiconductor memory or a hard disk. The analyzing unit 60, the calculating unit 62, and the determination unit 64 are, for example, electronic circuits. The analyzing unit 60, the calculating unit 62, and the determination unit 64 are, for example, a computer configured by a combination of hardware such as an arithmetic circuit and software such as a program.

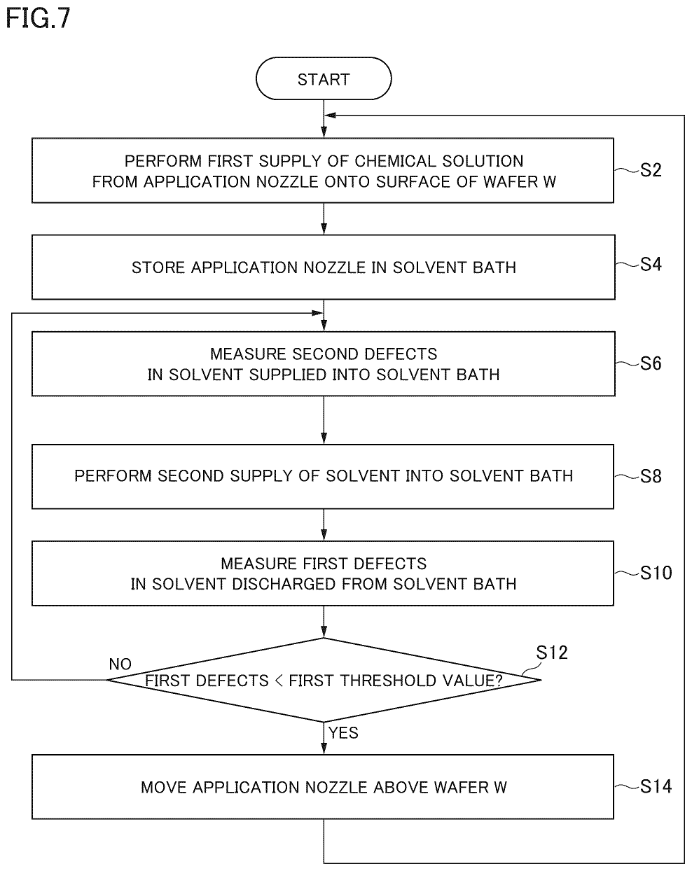

FIG. 7 is a flowchart showing the semiconductor device manufacturing method of embodiments.

First, first supply of a chemical solution from the application nozzle 86 onto the surface of the wafer W is performed (S2). Here, the wafer W is fixed by the spin chuck 82. In addition, the wafer W is rotated by the driving shaft 80 using the driving mechanism 78. As a result, a resist film is formed on the surface of the wafer W.

Then, the application nozzle 86 is stored in the solvent bath 70 (S4).

Then, using the second defects inspection apparatus 88b, second defects in the solvent supplied into the solvent bath 70 are measured (S6).

For example, using the second defects inspection apparatus 88b, a first threshold value is determined based on the second defects measured for the solvent supplied into the solvent bath 70. In addition, a threshold value that is arbitrarily determined in advance may be used as the first threshold value.

For example, when the second defects inspection apparatus 88b is an inspection apparatus that acquires the particle size (geometric size) of defects using the FPT method, the number of first particles containing metal and the number of bubbles or second particles different from the bubbles and the first particles in the solvent discharged from the solvent bath 70 are measured. In addition, for example, the number of first particles measured herein may be set as a second threshold value, and the number of bubbles or second particles different from the bubbles and the first particles measured herein may be set as a third threshold value. In addition, the second threshold value and the third threshold value may be used instead of the first threshold value, assuming that the first threshold value has the second threshold value and the third threshold value. In addition, threshold values that are arbitrarily determined in advance may be used as the second threshold value and the third threshold value.

For example, the first threshold value, the second threshold value, and the third threshold value may be stored in a semiconductor memory, a hard disk, and the like provided in the control device 76.

In addition, second defects may not be measured.

Then, second supply of the solvent into the solvent bath 70 is performed (S8). The application nozzle 86 is cleaned with the second supplied solvent. The solvent used for cleaning is discharged from the pipe 93 connected to the discharge path 70b through the discharge path 70b.

Then, using the first defects inspection apparatus 88a, first defects in the solvent discharged from the solvent bath 70 are measured (S10). Here, when the first defects inspection apparatus 88a is an inspection apparatus that acquires the particle size (geometric size) of defects using the FPT method, the number of first particles containing metal and the number of bubbles or second particles different from the bubbles and the first particles in the solvent discharged from the solvent bath 70 are measured.

Then, the first defects are compared with the first threshold value (S12). Then, for example, when the number of first defects is less than the first threshold value, the application nozzle 86 is moved from within the solvent bath 70 to above the wafer W (S14), and the first supply of the chemical solution from the application nozzle 86 onto the surface of the wafer W is performed (S2). On the other hand, when the number of first defects is equal to or greater than the first threshold value, second defects in the solvent supplied into the solvent bath 70 are measured (S6), the second supply of the solvent into the solvent bath 70 is performed (S8), and the first defects in the solvent discharged from the solvent bath 70 are measured (S10).

Here, a case where the second threshold value and the third threshold value are provided will be considered. When the number of first particles containing metal is less than the second threshold value and the number of bubbles or second particles different from the bubbles and the first particles is less than the third threshold value, the application nozzle 86 is moved from within the solvent bath 70 to above the wafer W, and the first supply of the chemical solution from the application nozzle 86 onto the surface of the wafer W is performed. On the other hand, when the number of first particles is equal to or greater than the second threshold value or the number of second particles is equal to or greater than the third threshold value, second defects in the solvent supplied into the solvent bath 70 are measured (S6), the second supply of the solvent into the solvent bath 70 is performed (S8), and the first defects in the solvent discharged from the solvent bath 70 are measured (S10).

As described above, assuming that the refractive index of the solvent to be measured is n0, the determination unit 64 determines that the defects are the metal particles A when the refractive index n satisfies “n<1” or “n0+(n0−1)<n”, and determines that the defects are the particles D or bubbles when the refractive index n satisfies “1≤n≤n0+(n0−1)”. For example, in a situation where it can be assumed that n0 particles D other than metal are present, defects can be determined to be bubbles when the refractive index n satisfies “1≤n≤n0+(n0−1)”. In addition, when the first defects are bubbles, the application nozzle 86 may be moved from within the solvent bath 70 to above the wafer W, and the first supply of the chemical solution from the application nozzle 86 onto the surface of the wafer W may be performed.

Next, the function and effect of the semiconductor device manufacturing method of embodiments will be described.

In the manufacturing of semiconductor devices in the semiconductor manufacturing factory 1000, dust can be mixed during the transportation of the wafer W. In addition, in the manufacturing of semiconductor devices in the semiconductor manufacturing factory 1000, dust caused by the chemical solution can be mixed. The dust caused by the chemical solution is dust generated by the precipitation of solid components in the chemical solution when the chemical solution adhering to the application nozzle 86 dries. Here, it has been difficult to carry out dust management by separating dust caused by the chemical solution from dust caused by other factors. For this reason, it has been difficult to quickly identify the source of dust. In addition, when the source of dust could not be identified quickly, it was later discovered that the dust had adhered to the surfaces of many wafers W on which the resist film was formed, resulting in the waste of many wafers W and chemical solutions.

Therefore, the semiconductor device manufacturing method of embodiments includes: performing a first supply of a chemical solution from an application nozzle onto a surface of a wafer; storing the application nozzle in a container; performing a second supply of a solvent into the container; measuring first defects in the solvent discharged from the container; performing the first supply of the chemical solution from the application nozzle onto the surface of the wafer when the number of first defects is less than a first threshold value; and continuing the second supply of the solvent into the container when the number of first defects is equal to or greater than the first threshold value.

The second supply of the solvent into the solvent bath 70 (container) is performed to clean the application nozzle. The solvent used for cleaning is discharged from the solvent bath 70, and the first defects are measured. Here, when the number of first defects is less than the first threshold value, this means that the dust adhering to the application nozzle has been sufficiently cleaned. Therefore, the first supply of the chemical solution from the application nozzle onto the surface of the wafer is performed. On the other hand, when the number of first defects is equal to or greater than the first threshold value, this means that the dust adhering to the application nozzle has not yet been sufficiently cleaned. Therefore, the second supply of the solvent into the solvent bath 70 is continued, and the cleaning of the application nozzle 86 is continued. In this manner, it is possible to provide a semiconductor device manufacturing method capable of applying a chemical solution with less dust.

By measuring the first defects using the FPT method, it is possible to determine whether the defects in the chemical solution are first particles containing metal or bubbles or second particles different from the bubbles and the first particles. This makes it easier to identify the cause of dust contamination. In addition, when measuring the first defects using the FPT method, it is preferable to include a step of performing the first supply of the chemical solution from the application nozzle onto the surface of the wafer when the first threshold value has the second threshold value and the third threshold value and the number of first particles is less than the second threshold value and the number of second particles is less than the third threshold value and include a step of continuing the second supply of the solvent into the container when the number of first particles is equal to or greater than the second threshold value or the number of second particles is equal to or greater than the third threshold value, because this makes it easier to identify the cause of dust contamination.

In addition, when measuring the first defects using the FPT method, a step of performing the first supply of the chemical solution from the application nozzle onto the surface of the wafer when the first defects are the bubbles may be further included. This is because if the first defects are the bubbles, it is believed that the first defects will not remain on the wafer W as foreign objects.

In addition, the first threshold value may also be determined by the second defects in the solvent before the second supply into the solvent bath 70 is performed. By comparing the first defects with the second defects, the cause of the dust contamination can be more easily identified. In addition, since the semiconductor manufacturing process can be immediately interrupted when an increase in second defects is detected, unnecessary use of chemical solutions or the wafers W can be suppressed.

According to the semiconductor device manufacturing method of embodiments, it is possible to provide a semiconductor device manufacturing method capable of easily manufacturing a semiconductor device.

While certain embodiments have been described, these embodiments have been presented by way of example only, and are not intended to limit the scope of the inventions. Indeed, the semiconductor device manufacturing method described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
performing a first supply of a chemical solution from an application nozzle onto a surface of a wafer;
storing the application nozzle in a container;
performing a second supply of a solvent into the container;
measuring first defects in the solvent discharged from the container;
performing the first supply of the chemical solution from the application nozzle onto the surface of the wafer when the number of first defects is less than a first threshold value; and
continuing the second supply of the solvent into the container when the number of first defects is equal to or greater than the first threshold value.

2. The semiconductor device manufacturing method according to claim 1,
wherein measuring the first defects in the solvent discharged from the container includes:
sending the solvent to a transparent column;
irradiating the solvent in the column with irradiation light;
imaging scattered light emitted from the first defects by the irradiation;
determining a diffusion coefficient of the first defects from the imaged scattered light;
calculating a particle size of the first defects and a refractive index of the first defects using the diffusion coefficient; and
determining using the refractive index whether the first defects are
first particles containing metal, or
bubbles or second particles different from the bubbles and the first particles.

3. The semiconductor device manufacturing method according to claim 2,
wherein the first threshold value has a second threshold value and a third threshold value, and
the semiconductor device manufacturing method further comprising:
performing the first supply of the chemical solution from the application nozzle onto the surface of the wafer when the number of first particles is less than the second threshold value and the number of second particles is less than the third threshold value; and
continuing the second supply of the solvent into the container when the number of first particles is equal to or greater than the second threshold value or the number of second particles is equal to or greater than the third threshold value.

4. The semiconductor device manufacturing method according to claim 2, further comprising:
performing the first supply of the chemical solution from the application nozzle onto the surface of the wafer when the first defects are the bubbles.

5. The semiconductor device manufacturing method according to claim 1,
wherein the first threshold value is determined based on second defects in the solvent before the second supply into the container is performed.

6. The semiconductor device manufacturing method according to claim 3,
wherein the second threshold value and the third threshold value are determined based on second defects in the solvent before the second supply into the container is performed.
